(19) United States
(12) Patent Application Publication
(10) Pub. No.: US 2014/0183498 A1
(43) Pub. Date: Jul. 3, 2014

(54) Thin Film Silicon Nitride Barrier Layers On Flexible Substrate

(71) Applicant: Saint-Gobain Performance Plastics Corporation, Aurora, OH (US)

(72) Inventors: Anirban Dhar, Aubervilliers Cedex (FR); Alessandro Giassi, Aubervilliers Cedex (FR)

(73) Assignee: Saint-Gobain Performance Plastics Corporation, Aurora, OH (US)

(21) Appl. No.: 14/136,951

(22) Filed: Dec. 20, 2013

Related U.S. Application Data
(60) Provisional application No. 61/805,782, filed on Mar. 27, 2013.

(30) Foreign Application Priority Data
Dec. 31, 2012 (FR) 12/62975

(51) Int. Cl. H01L 51/52; H01L 51/44; B32B 27/06

(52) U.S. Cl. CPC H01L 51/5253; B32B 27/06; H01L 51/448
USPC 257/40; 428/446; 428/339

(57) ABSTRACT

An article comprising a polymeric substrate and at least one inorganic barrier layer, wherein the inorganic barrier layer has a stress not greater than about 400 MPa and a density of at least about 1.5 g/cm³. The article is preferably an optical device, such as an organic light emitting diode (OLED) or a photovoltaic (PV) module, wherein a silicon nitride barrier layer has been directly deposited on a flexible polymeric substrate via plasma enhanced chemical vapor deposition (PECVD).

### CROSS-REFERENCE TO RELATED APPLICATION

The present application claims priority from French Patent Application No. 12/62975, filed Dec. 31, 2012, entitled “THIN FILM SILICON NITRIDE BARRIER LAYERS ON FLEXIBLE SUBSTRATE”, naming as inventors Anirban Dhar and Alessandro Giassi, and U.S. Provisional Patent Application No. 61/805,782, filed Mar. 27, 2013, entitled “THIN FILM SILICON NITRIDE BARRIER LAYERS ON FLEXIBLE SUBSTRATE”, naming as inventors Anirban Dhar and Alessandro Giassi, which applications are incorporated by reference herein in their entirety.

### TECHNICAL FIELD

The present invention relates to an inorganic thin film barrier layer deposited on a polymeric substrate for protection of a moisture sensitive element, such as an organic light-emitting diode or a photovoltaic cell. The invention also relates to an article comprising such a barrier layer component, and to a process for fabricating such component.

### BACKGROUND ART

Functional elements of an optical device are liable to degradation due to the effect of environmental conditions, especially due to the effect of exposure to moisture and air. As an example, in the case of an Organic Light Emitting Diode (OLED) or organic photovoltaic cells, the organic materials are particularly sensitive to the environmental conditions.

To protect the functional elements of an electronic device from degradation due to exposure to moisture, it is known to fabricate the device with a laminated structure in which the functional elements are encapsulated with a protection substrate.

Depending on the application of the device, the protection substrates may be made of glass or an organic polymeric material. An OLED or a photovoltaic cell encapsulated with a flexible polymeric substrate, rather than a glass substrate, has the advantage of being pliable, ultra-thin and light.

However, it has been found that, when an electronic device comprises an organic polymeric substrate positioned against a functional element sensitive to air and/or moisture, the device has a high rate of degradation. This is because the polymeric substrate tends to store moisture and promotes the migration of contaminating species such as water vapor or oxygen into the sensitive functional element, and therefore impairs the properties of this functional element.

To protect the water-sensitive electronic parts in such devices, it is known to apply a set of barrier layers on top of the polymeric substrate. However, especially in the case of a flexible substrate, the deposition of thin film barrier layers is quite challenging as relatively-rigid inorganic thin films on flexible substrates have a tendency to develop easily cracks and delamination, which degrades their barrier properties. Moreover, commonly known applications of stacks of multiple organic barrier layers require extensive manufacturing efforts, and it is desired to have a more economical and simpler method to improve the barrier performance.

### SUMMARY OF THE INVENTION

The present invention provides an article comprising a polymeric substrate and at least one inorganic barrier layer, wherein the inorganic barrier layer has a stress not greater than about 400 MPa and a density of at least about 1.5 g/cm³. The article is preferably an optical device, such as an organic light emitting diode (OLED) or a photovoltaic (PV) module.

In one aspect, the inorganic barrier layer is a silicon nitride barrier layer deposited via Plasma Enhanced Chemical Vapor Deposition (PECVD) on a flexible polymeric substrate. It has been discovered that the best barrier performance of the silicon nitride layer against moisture is obtained at a combination of high density and a low stress.

Another subject of the invention is a method of making a silicon nitride layer deposited via PECVD on the polymeric substrate. The method includes specifically selected ranges for reaction key parameters, such as the molar ratio of SiH₄ to NH₃, reaction temperature, pressure and applied power to obtain desired high densities and low stress in the deposited silicon nitride layers.

Other features and advantages of the present invention will be set forth in the detailed description that follows, and will be apparent, in part, from the description or may be learned by practice of the invention. The invention will be realized and attained by the methods and devices particularly pointed out in the written description and claims hereof. This description is being given solely by way of example and with reference to the appended drawings

### BRIEF DESCRIPTION OF THE DRAWINGS

FIG. 1 includes a graph showing the moisture barrier performance of silicon nitride monolayers in dependence to their densities and stress-values.

FIG. 2 demonstrates long term moisture barrier performance of silicon nitride monolayers according to the present invention in comparison to a commercial reference FG500 and comparative examples.

FIG. 3 shows water vapor transmission rate (WVTR) of two representative examples in comparison to commercial reference FG500 using MOCON Aquatran test.

FIG. 4 demonstrates the influence of a thermal cycle on the moisture barrier performance of 3 silicon nitride layers according to the present invention in comparison to commercial reference FG500.

FIG. 5 shows an example to determine the critical thickness of a silicon nitride layer for best barrier performance.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

As used herein, the terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B is true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the inorganic layer depositing arts and corresponding manufacturing arts.

The present invention provides an article comprising a polymeric substrate and at least one inorganic barrier layer, wherein the inorganic barrier layer has a stress not greater than about 400 MPa and a density of at least about 1.5 g/cm³. The article may be, for example, an optical device comprising a moisture-sensitive electronic part.

In a preferred embodiment, the aforementioned polymeric substrate is flexible.

The polymeric substrate may be a thermoplastic or a thermoset. For example the polymeric substrate may be a polyethylene terephthalate (PET), a polyethylene naphthalate (PEN), a polycarbonate, polyurethane, a polymethyl methacrylate, a polyamide, a fluoropolymer or any combination thereof. Preferred fluoropolymers are ethylene-tetrafluoroethylene (ETFE), polyvinylidene fluoride (PVDF), polychlorotrifluoroethylene (PCTFE), ethylene-chlorotrifluoroethylene (ECTFE), fluorinated ethylene-propylene copolymers (FEP) and perfluoroalkyloxy polymer (PFA). In a most preferred embodiment the polymeric substrate may be a polyethylene terephthalate (PET) or polyethylene naphthalate (PEN).

The polymeric substrate may further have a surface roughness Ra in the range of 0.001 nm to 10 nm. For example, the surface roughness may be at least 0.1 nm, at least 0.6 nm, at least 0.8 nm, as least 1.0 nm, at least 1.2 nm, at least 1.4 nm, at least 1.6 nm, at least 1.8 nm, not greater than 9 nm, not greater than 8 nm, not greater than 7 nm, or not greater than 6 nm. Preferably, the surface roughness is in the range between 1 nm and 5.5 nm.

In another aspect, the polymeric substrate is transparent. In the context of the invention, a layer or a stack of layers is considered to be transparent when it is at least 80% transmissive within at least the useful wavelength range for the intended application. As an example, in the case of a photovoltaic device comprising photovoltaic cells, each transparent layer is transparent within the wavelength range between 400 nm and 2500 nm, these bringing the useful wavelength for this type of cell. Furthermore, in certain embodiments, the transparency may be at least 85%, such as at least 90%, at least 92%, at least 95%, at least 98%, at least 99%, or at least 99.5%.

In one embodiment of the invention, the at least one inorganic barrier layer is deposited directly on the polymeric substrate. In another embodiment, one or more intermediate layer(s) may be contained between the polymeric substrate and the at least one inorganic barrier layer.

In a further embodiment, the at least one inorganic barrier layer has a transparency of at least about 60% in the wavelength range between 400 nm and 760 nm, such as at least 70%, at least 75%, at least 80%, at least 85%, 90%, at least 95%, at least 98%, at least 99%, or at least 99.5%.

The inorganic barrier layer may comprise a metal oxide, a metal nitride, a metal oxynitride or any combination thereof. The aforementioned metal may be Si, Al, Sn, Zn, Zr, Ti, Hf, Bi, Ta, or any combination thereof. Preferably, the metal is Si or Al. More preferable, the metal is Si. Most preferable, the inorganic barrier layer is made of silicon nitride.

In one aspect of the invention, the inorganic barrier layer is deposited via Chemical Vapor Deposition (CVD) or Atomic Layer Deposition (ALD). Preferably, the Chemical Vapor Deposition (CVD) is Plasma Enhanced Chemical Vapor Deposition (PECVD).

It has been surprisingly discovered that in order to obtain a good moisture barrier property of an inorganic barrier layer, a low stress and a high density of the layer is advantageous. This is especially advantageous for the making efficient and stable thin film barrier layers on flexible substrates.

According to one aspect of the present invention, the stress in the barrier layer is between 400 MPa and 0 MPa. Preferably, the stress is not greater than about 390 MPa, such as not greater than about 380 MPa, not greater than about 370 MPa, not greater than about 360 MPa, not greater than about 350 MPa, not greater than about 340 MPa, not greater than about 330 MPa, not greater than about 320 MPa, not greater than about 310 MPa, not greater than about 300 MPa, not greater than about 290 MPa, not greater than about 280 MPa, not greater than about 270 MPa, not greater than about 260 MPa, not greater than about 250 MPa, not greater than about 240 MPa, not greater than about 230 MPa, not greater than about 220 MPa, not greater than about 210 MPa, not greater than about 200 MPa, not greater than about 190 MPa, not greater than about 180 MPa, not greater than about 170 MPa, not greater than about 160 MPa, not greater than about 150 MPa, not greater than about 140 MPa, not greater than about 130 MPa, not greater than about 120 MPa, not greater than about 110 MPa, not greater than about 100 MPa, not greater than about 90 MPa, not greater than about 80 MPa, not greater than about 70 MPa, not greater than about 60 MPa, not greater than about 50 MPa, not greater than about 40 MPa, not greater than about 30 MPa, not greater than about 20 MPa, or not greater than about 10 MPa.

Furthermore, the density of the inorganic barrier layer is at least about 1.5 g/cm³, such as is at least about 1.55 g/cm³, such as at least about 1.6 g/cm³, at least about 1.65 g/cm³, at least about 1.7 g/cm3, at least about 1.75 g/cm³, at least about 1.8 g/cm³, at least about 1.85 g/cm³, at least about 1.9 g/cm³, at least about 1.95 g/cm³, at least about 2 g/cm³, at least about 2.05 g/cm³, at least about 2.1 g/cm³, at least about 2.15 g/cm³, at least about 2.2 g/cm³, at least about 2.25 g/cm³, at least about 2.3 g/cm³, at least about 2.35 g/cm³, at least about 2.4 g/cm³, at least about 2.45 g/cm³, at least about 2.5 g/cm³, at least about 2.55 g/cm³, at least about 2.6 g/cm³, at least about 2.65 g/cm³, at least about 2.7 g/cm³, at least about 2.75 g/cm³, at least about 2.8 g/cm³, at least about 2.85 g/cm³, at least about 2.9 g/cm³, at least about 3 g/cm³, at least about 3.05 g/cm³, at least about 3.1 g/cm³, at least about 3.15 g/cm³, at least about 3.2 g/cm³, at least about 3.25 g/cm³, at least about 3.3 g/cm³, or at least about 3.35 g/cm³. Preferably, the density is in an area between about 2.0 and about 3.0 g/cm³.

In one embodiment, the stress in the inorganic barrier layer is not greater than about 170 MPa and the density is at least about 2.0 g/cm³. In another embodiment, the stress is not greater than about 350 MPa and the density is at least about 2.5 g/cm³.

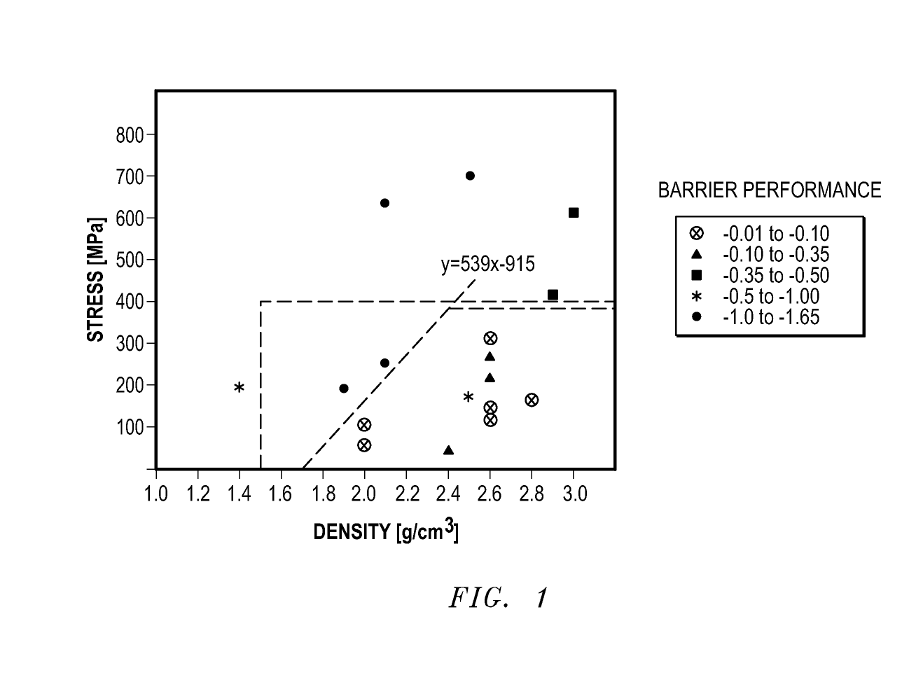

FIG. 1 shows the moisture barrier performance of several silicon nitride monolayers in dependence to their densities and stress-values. It can be seen that the area with the best moisture barrier performance is right to an inclining line with the equation y=539x−915 (y, being stress, and x being density), and ends at a plateau of about 400 MPa stress. Accordingly, the preferred stress and density in the barrier layers of the present invention correspond to the following formula:

Stress<S·Density+I,

with S having a value not greater than 550 MPa·cm³/g, such as not greater than 540 MPa·cm³/g, not greater than 530 MPa·cm³/g, not greater than 520 MPa·cm³/g, not greater than 510 MPa·cm³/g, not greater than 500 MPa·cm³/g, not greater than 490 MPa·cm³/g, not greater than 470 MPa·cm³/g, not greater than 450 MPa·cm³/g, not greater than 430 MPa·cm³/g, not greater than 410 MPa·cm³/g, not greater than 350 MPa·cm³/g, not greater than 300 MPa·cm³/g, or not greater than 250 MPa·cm³/g; and wherein I is not greater than −400 MPa, such as not greater than −500 MPa, not greater than −600 MPa, not greater than −700 MPa, not greater than −800 MPa, not greater than −900 MPa, up to −1000 MPa; preferably, S is 539 MPa·cm3/g and I is −915 MPa.

The inorganic barrier layer having above-cited high densities and low stress values, may correspond to a water vapor transmission rate (WVTR) of not greater than 0.01 g/m2/day, such as not greater than 0.009 g/m²/day, not greater than 0.008 g/m²/day, not greater than 0.007 g/m²/day, not greater than 0.006 g/m²/day, not greater than 0.005 g/m²/day, not greater than 0.004 g/m²/day, not greater than 0.003 g/m²/day, not greater than 0.002 g/m²/day, not greater than 0.001 g/m²/day, or not greater than 0.0001 g/m²/day.

The thickness of the inorganic barrier layer may be at least about 10 nm, such as at least about 20 nm, at least about 30 nm, at least about 40 nm at least about 50 nm, at least about 70 nm, at least about 100 nm, at least about 150 nm, at least about 200 nm, at least about 250 nm, at least about 300 nm, at least about 350 nm or at least about 400 nm.

The present invention further provides a method of depositing silicon nitride on a polymeric substrate. The silicon nitride may be deposited via Chemical Vapor Deposition (CVD) or Atomic Layer Deposition (ALD). Preferably, the Chemical Vapor Deposition is conducted via Plasma Enhanced Chemical Vapor Deposition (PECVD).

The PECVD method of the present invention comprises varying four key parameters: 1) the molar ratio of SiH₄ to NH₃ being within the range between about 0.4 to about 1.0; 2) a temperature in the reaction chamber being between about 70° C. to about 130° C.; 3) adjusting the pressure in the reaction chamber between about 225 μbar to about 500 μbar; and 4) emitting a radio frequency from the reactor at a power between about 200 W to about 450 W. Preferably, the molar ratio of SiH₄ to NH₃ is between about 0.5 to about 0.9, more preferably, between about 0.58 and about 0.8. The chamber temperature is preferred between about 80° C. to about 120° C., and more preferred between about 100° C. to about 120° C.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the items as listed below.

Item 1. An article comprising a polymeric substrate, and at least one inorganic barrier layer, wherein the inorganic barrier layer has a stress not greater than about 400 MPa and a density of at least about 1.5 g/cm³.

Item 2. An encapsulated optical device comprising an electronic part; and a barrier stack overlying the electronic part, wherein the barrier stack comprises a polymeric substrate, and an inorganic barrier layer, the inorganic barrier layer having a stress of not greater than about 400 MPa and a density of at least about 1.5 g/cm³.

Item 3. The encapsulated optical device of item 2, wherein the encapsulated optical device is an Organic Light Emitting Diode (OLED) or a photovoltaic (PV) module.

Item 4. The article or the encapsulated optical device according to any one of items 1 through 3, wherein the substrate is flexible.

Item 5. The article or the encapsulated optical device according to any one of items 1 through 4, wherein the stress is not greater than about 390 MPa, such as not greater than about 380 MPa, not greater than about 370 MPa, not greater than about 360 MPa, not greater than about 350 MPa, not greater than about 340 MPa, not greater than about 330 MPa, not greater than about 320 MPa, not greater than about 310 MPa, not greater than about 300 MPa, not greater than about 290 MPa, not greater than about 280 MPa, not greater than about 270 MPa, not greater than about 260 MPa, not greater than about 250 MPa, not greater than about 240 MPa, not greater than about 230 MPa, not greater than about 220 MPa, not greater than about 210 MPa, not greater than about 200 MPa, not greater than about 190 MPa, not greater than about 180 MPa, not greater than about 170 MPa, not greater than about 160 MPa, not greater than about 150 MPa, not greater than about 140 MPa, not greater than about 130 MPa, not greater than about 120 MPa, not greater than about 110 MPa, not greater than about 100 MPa, not greater than about 90 MPa, not greater than about 80 MPa, not greater than about 70 MPa, not greater than about 60 MPa, not greater than about 50 MPa, not greater than about 40 MPa, not greater than about 30 MPa, not greater than about 20 MPa, or not greater than about 10 MPa.

Item 6. The article or the encapsulated optical device according to any one of items 1 through 4, wherein the stress is at least about 0.001 MPa, such as at least about 20 MPa, at least about 30 MPa, at least about 40 MPa, at least about 50 MPa, at least about 60 MPa, at least about 70 MPa, at least about 80 MPa, at least about 90 MPa, at least about 100 MPa, at least about 110 MPa, at least about 120 MPa, at least about 130 MPa, at least about 140 MPa, at least about 150 MPa, at least about 160 MPa, at least about 170 MPa, at least about 180 MPa, at least about 190 MPa, at least about 200 MPa, at least about 210 MPa, at least about 220 MPa, at least about 230 MPa, at least about 240 MPa, at least about 250 MPa, at least about 260 MPa, at least about 270 MPa, at least about 280 MPa, at least about 300 MPa, at least about 310 MPa, at least about 320 MPa, at least about 330 MPa, at least about 340 MPa, at least about 350 MPa, at least about 360 MPa, at least about 370 MPa, at least about 380 MPa, or at least about 390 MPa.

Item 7. The article or the encapsulated optical device according to any one of items 1 through 4, wherein the density is at least about 1.55 g/cm³, such as at least about 1.6 g/cm³, at least about 1.65 g/cm³, at least about 1.7 g/cm³, at least about 1.75 g/cm³, at least about 1.8 g/cm³, at least about 1.85 g/cm³, at least about 1.9 g/cm³, at least about 1.95 g/cm³, at least about 2 g/cm³, at least about 2.05 g/cm³, at least about 2.1 g/cm³, at least about 2.15 g/cm³, at least about 2.2 g/cm³, at least about 2.25 g/cm³, at least about 2.3 g/cm³, at least about 2.35 g/cm³, at least about 2.4 g/cm³, at least about 2.45 g/cm³, at least about 2.5 g/cm³, at least about 2.55 g/cm³, at least about 2.6 g/cm³, at least about 2.65 g/cm³, at least about 2.7 g/cm³, at least about 2.75 g/cm³, at least about 2.8 g/cm³, at least about 2.85 g/cm³, at least about 2.9 g/cm³, at least about 3 g/cm³, at least about 3.05 g/cm³, at least about 3.1 g/cm³, at least about 3.15 g/cm³, at least about 3.2 g/cm³, at least about 3.25 g/cm³, at least about 3.3 g/cm³, or at least about 3.35 g/cm³.

Item 8. The article or the encapsulated optical device according to any one of items 1 through 4, wherein the density is not greater than about 3.3 g/cm³, not greater than about 3.25 g/cm³, not greater than about 3.2 g/cm³, not greater than about 3.15 g/cm³, not greater than about 3.1 g/cm³, not greater than about 3.05 g/cm³, not greater than about 3 g/cm³, not greater than about 2.95 g/cm³, not greater than about 2.9 g/cm³, not greater than about 2.85 g/cm³, not greater than about 2.8 g/cm³, not greater than about 2.75 g/cm³, not greater than about 2.7 g/cm³, not greater than about 2.65 g/cm³, not greater than about 2.6 g/cm³, not greater than about 2.55 g/cm³, not greater than about 2.5 g/cm³, not greater than about 2.45 g/cm³, not greater than about 2.4 g/cm³, not greater than about 2.35 g/cm³, not greater than about 2.3 g/cm³, not greater than about 2.25 g/cm³, not greater than about 2.2 g/cm³, not greater than about 2.15 g/cm³, not greater than about 2.1 g/cm³, not greater than about 2.05 g/cm³, not greater than about 2 g/cm³, not greater than about 1.95 g/cm³, not greater than about 1.9 g/cm³, not greater than about 1.85 g/cm³, not greater than about 1.8 g/cm³, not greater than about 1.75 g/cm³, not greater than about 1.7 g/cm³, not greater than about 1.65 g/cm³, not greater than about 1.6 g/cm³, or not greater than about 1.55 g/cm³.

Item 9. The article or the encapsulated optical device according to any one of items 1 through 4, wherein stress and density are related according to the following formula Stress<S*Density+I, wherein S has a value not greater than 550 MPa·cm³/g, such as not greater than 540 MPa·cm³/g, not greater than 530 MPa·cm³/g, not greater than 520 MPa·cm³/g, not greater than 510 MPa·cm³/g, not greater than 500 MPa·cm³/g, not greater than 490 MPa·cm³/g, not greater than 470 MPa·cm³/g, not greater than 450 MPa·cm³/g, not greater than 430 MPa·cm³/g, not greater than 410 MPa·cm³/g, not greater than 350 MPa·cm³/g, not greater than 300 MPa·cm³/g, or not greater than 250 MPa·cm³/g; and wherein I is not greater than −400 MPa, such as not greater than −500 MPa, not greater than −600 MPa, not greater than −700 MPa, not greater than −800 MPa, not greater than −900 MPa, up to −1000 MPa.

Item 10. The article or the encapsulated optical device according to item 9, wherein S is 539 MPa·cm³/g and I is −915 MPa.

Item 11. The article or the encapsulated optical device according to any one of items 1 through 4, wherein the inorganic barrier layer having a stress of not greater than about 170 MPa and a density of at least about 2.0 g/cm³.

Item 12. The article or the encapsulated optical device according to any one of items 1 through 4, wherein the inorganic barrier layer having a stress of not greater than about 350 MPa and a density of at least about 2.5 g/cm³.

Item 13. The article or the encapsulated optical device according to any one of items 1 through 4, wherein the polymeric substrate is a thermoplastic or a thermoset.

Item 14. The article or the encapsulated optical device according to items 1 through 4, wherein the polymeric substrate is selected from the group consisting of polyethylene terephthalate (PET), polyethylene naphthalate (PEN), polycarbonate, polyurethane, polymethyl methacrylate, polyamide, and fluoropolymer.

Item 15. The article or the encapsulated optical device of item 14, wherein the polymeric substrate consists essentially of polyethylene terephthalate (PET), polyethylene naphthalate (PEN), or any combination thereof.

Item 16. The article or the encapsulated optical device of item 14, wherein the fluoropolymer is selected from the group consisting of ethylene-tetrafluoroethylene (ETFE), polyvinylidene fluoride (PVDF), polychlorotrifluoroethylene (PCTFE), ethylene-chlorotrifluoroethylene (ECTFE), fluorinated ethylene-propylene copolymers (FEP) and perfluoroalkyloxy polymer (PFA).

Item 17. The article or the encapsulated optical device according to any one of items 1 through 4, wherein the polymeric substrate is a transparent polymer with a transparency from 400 nm to 750 nm of at least 80%.

Item 18. The article or the encapsulated optical device according to item 17, wherein the transparency is at least 85%, such as at least 90%, at least 92%, at least 94%, at least 96%, at least 98%, or at least 99%.

Item 19. The article or the encapsulated optical device according to any one of items 1 through 4, wherein the barrier layer is transparent with a transparency of at least 60%.

Item 20. The article or the encapsulated optical device according to item 19, wherein the transparency is at least 65%%, such as at least 70%, at least 75%, at least 80%, at least 85%, 90%, at least 95%, at least 98%, at least 99%, or at least 99.5%.

Item 21. The article or the encapsulated optical device according to any one of items 1 through 4, wherein the substrate has a surface roughness Rₐ of at least 0.001 nm, such as at least 0.1 nm, at least 0.6 nm, at least 0.8 nm, at least 0.9 nm, at least 1.0 nm, at least 1.2 nm, at least 1.4 nm, at least 1.6 nm, or at least 1.8 nm.

Item 22. The article or the encapsulated optical device according to any one of items 1 through 4, wherein the substrate has a surface roughness Rₐ of not greater than 10 nm, such as not greater than 9 nm, not greater than 8 nm, or not greater than 7 nm, not greater than 6 and not greater 5.5 nm

Item 23. The article or the encapsulated optical device according to any one of items 1 through 4, wherein the inorganic barrier layer comprises a metal oxide, a metal nitride, a metal oxynitride, or any combination thereof.

Item 24. The article or the encapsulated optical device of item 23, wherein the metal is selected from the group consisting of Si, Al, Sn, Zn, Zr, Ti, Hf, Bi, Ta, or any alloy thereof.

Item 25. The article or the encapsulated optical device of item 24, wherein the metal is Si or Al.

Item 26. The article or the encapsulated optical device of item 25, wherein the metal consist essentially of Si.

Item 27. The article or the encapsulated optical device of item 23, wherein the inorganic barrier layer comprises silicon nitride.

Item 28. The article or the encapsulated optical device of item 27, wherein the inorganic barrier layer consists essentially of silicon nitride

Item 29. The article or the encapsulated optical device according to any one of items 1 through 4, wherein the inorganic barrier layer has been made by Chemical Vapor Deposition (CVD) or Atomic Layer Deposition (ALD).

Item 30. The article or the encapsulated optical device of item 29, wherein the Chemical Vapor Deposition (CVD) is Plasma Enhanced Chemical Vapor Deposition (PECVD).

Item 31. The article or the encapsulated optical device according to any one of items 1 through 4, wherein the inorganic barrier layer has a water vapor transmission rate (WVTR) of not greater than 0.01 g/m²/day, such as not greater than 0.009 g/m²/day, not greater than 0.008 g/m²/day, not greater than 0.007 g/m²/day, not greater than 0.006 g/m²/day, not greater than 0.005 g/m²/day, not greater than 0.004 g/m²/day, not greater than 0.003 g/m²/day, not greater than 0.002 g/m²/day, not greater than 0.001 g/m²/day, or not greater than 0.0001 g/m²/day.

Item 32. The article or the encapsulated optical device according to any one of items 1 through 4, wherein the thickness of the at least one inorganic barrier layer is at least about 10 nm, at least about 20 nm, at least about 30 nm, at least about 40 nm at least about 50 nm, such as at least about 70 nm, at least about 100 nm, at least about 150 nm, at least about 200 nm, at least about 250 nm, at least about 300 nm, at least about 350 nm or at least about 400 nm.

Item 33. The article or the encapsulated optical device according to any one of items 1 through 4, wherein no interfacial layer is contained between the substrate and the at least one inorganic barrier layer.

Item 34. A method of making a silicon nitride layer on a polymeric substrate, wherein the silicon nitride layer has a stress not greater than about 400 MPa and a density of at least about 1.5 g/cm³, the method comprising depositing silicon nitride on the polymeric substrate.

Item 35. The method according to item 34, wherein the depositing includes Chemical Vapor Deposition (CVD) or Atomic Layer Deposition (ALD)

Item 36. The method according to item 35, wherein the Chemical Vapor Deposition (CVD) is Plasma Enhanced Chemical Vapor Deposition (PECVD).

Item 37. The method of making a silicon nitride layer on a polymeric substrate according to item 36, wherein the Plasma Enhanced Chemical Vapor Deposition is conducted in a chamber having a reactor, the method further comprising adding SiH₄ and NH₃ to the chamber, a molar ratio of SiH₄/NH₃ being between about 0.4 to about 1.0; heating the chamber to a temperature between about 70° C. to about 130° C.; adjusting a pressure in the chamber between about 225 μbar to about 500 μbar; and emitting radio frequency from the reactor at a power between about 200 W to about 450 W.

Item 38. The method of making a silicon nitride layer on a polymeric substrate according to item 37, wherein the molar ratio of SiH₄ to NH₃ is between about 0.5 to about 0.9; such as between about 0.58 to about 0.79; and wherein the chamber temperature is between about 80° C. to about 120° C., such as between about 100° C. and 120° C.

The following examples are illustrative of the present invention, and are not to be construed as limiting the scope of the invention. Variations and equivalents of these examples will be apparent to those of skill in the art in light of the present disclosure, the drawings, and the claims herein. Unless otherwise stated, all percentages are by weight of the total composition.

### EXAMPLES

The following non-limiting examples illustrate the present invention.

### Examples 1-7

Table 1 shows a summary of 7 examples of silicon nitride monolayers produced via PECVD on a flexible PET substrate representative to the present invention and 4 comparative examples C1 to C4 which do not fall under the present invention. For each silicon nitride monolayer, thickness, density, stress, refractive index and moisture barrier performance have been measured. The values in Table 1 are organized according to the barrier performance of the layers, with the silicon nitride layer having the best barrier performance being on top. Table 1 further includes four key parameters for the PECVD process: SiH₄ to NH₃ ratio, temperature, pressure and power.

The values of the moisture barrier performance in Table 1 and FIG. 1 are defined as the logarithm of the percentage moisture content released inside a test cell after 111 hours. The best barrier performance relates to the range of −0.01 to −0.35 ln (% moisture). Values having not an acceptable barrier performance are in the range of −1.0 to −1.65, and indicated as Comparative Examples C1 to C4.

TABLE 1

| | Gas- | Pressure | Temp. | Power | Thickness | Density | Stress | Refr. | Barrier |
|---|---|---|---|---|---|---|---|---|---|
| Ex. | ratio | [MPa] | [° C.] | [Watt] | [nm] | [g/cm³] | [MPa] | Index | Perform. |
| E1 | 0.4 | 500 | 120 | 200 | 204 | 2.0 | 65.3 | 1.79 | −0.014 |
| E2 | 0.8 | 500 | 80 | 200 | 231 | 2.0 | 103.3 | 1.81 | −0.041 |
| E3 | 0.4 | 500 | 120 | 450 | 281 | 2.6 | 307.6 | 1.82 | −0.074 |
| E4 | 0.6 | 362.5 | 100 | 325 | 215 | 2.6 | 129.9 | 1.85 | −0.087 |
| E5 | 0.8 | 225 | 80 | 200 | 169 | 2.6 | 124.7 | 1.86 | −0.088 |
| E6 | 0.6 | 362.5 | 100 | 325 | 246 | 2.8 | 167.2 | 1.82 | −0.097 |
| E7 | 0.4 | 500 | 80 | 200 | 209 | 2.4 | 38.1 | 1.79 | −0.125 |
| C1 | 0.8 | 225 | 80 | 450 | 247 | 2.5 | 699 | 1.85 | −1.071 |
| C2 | 0.8 | 225 | 120 | 200 | 192 | 1.9 | 195.9 | 1.81 | −1.272 |
| C3 | 0.8 | 225 | 120 | 450 | 244 | 2.1 | 637.6 | 1.80 | −1.517 |
| C4 | 0.4 | 225 | 120 | 200 | 196 | 2.1 | 254.9 | 1.77 | −1.634 |

The moisture barrier performance has been evaluated by measuring the loss of moisture inside a moisture-trapped encapsulate compartment across a barrier layer on polymer. The initial percentage of water inside the compartment is measured just after the encapsulation and is marked as 100%, and then the water percentage inside the encapsulate compartment is measured periodically to obtain a % moisture vs. time curve. For graphical demonstration, the curve is converted into ln (% moisture) vs. time. The change in water concentration inside the encapsulate compartment is proportional to the Water Vapor Transmission Rate (WVTR), wherefore the lower the slope of the curves, the lower the associated WVTR.

FIG. 1 shows the moisture barrier performance of a variety of silicon nitride monolayers, including all examples and comparative examples listed in Table 1, in dependence to their densities and stress. The graph demonstrates that the best barrier performance is obtained at high densities at about 2.0 g/cm³ and greater and a stress lower that about 400 MPa. It can be further seen that an inclining line (with equation y=539x−915) more specifically allows appropriate grouping of density and stress parameters in order to predict good barrier performance of the silicon nitride layers.

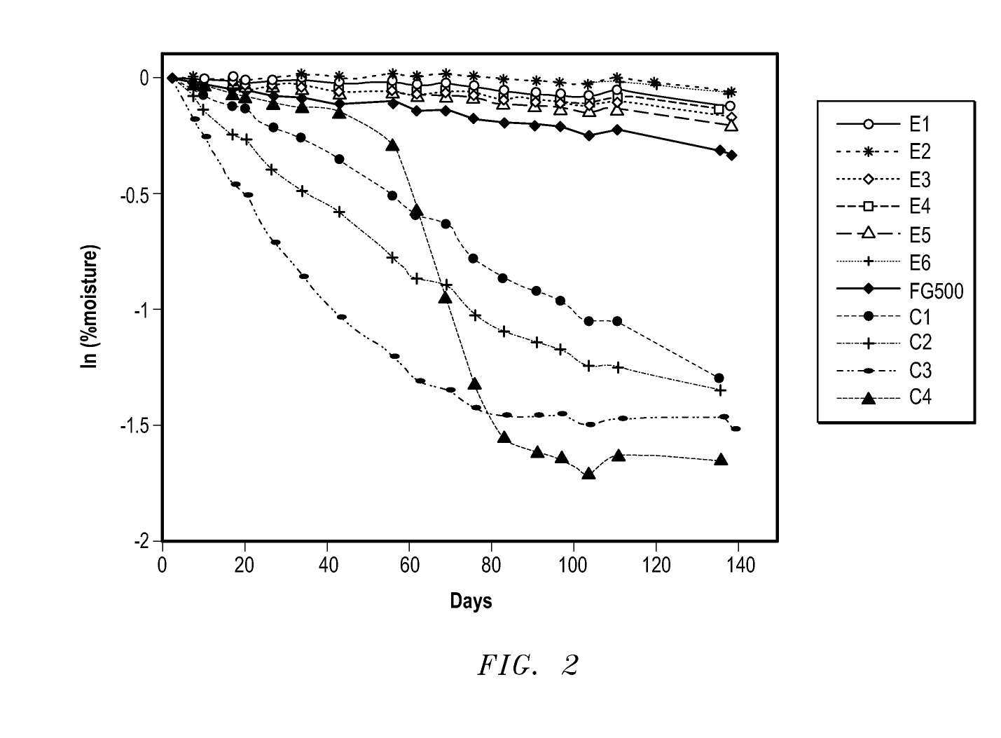

FIG. 2 shows the barrier performance of silicon nitride layers of Examples 1-6 and Comparative Examples 1-4 over a time period of 140 days. FIG. 2 further includes a commercial reference, FG500 from Vitex systems, which consists of a fivefold-dyad system. FIG. 2 demonstrates that all representative Examples E1-E6 have a better barrier performance than the reference barrier probe FG500 . Moreover, it can be seen that Comparative Examples C1-C4 have in comparison to reference FG500 a much worse moisture bather performance.

### Example 8

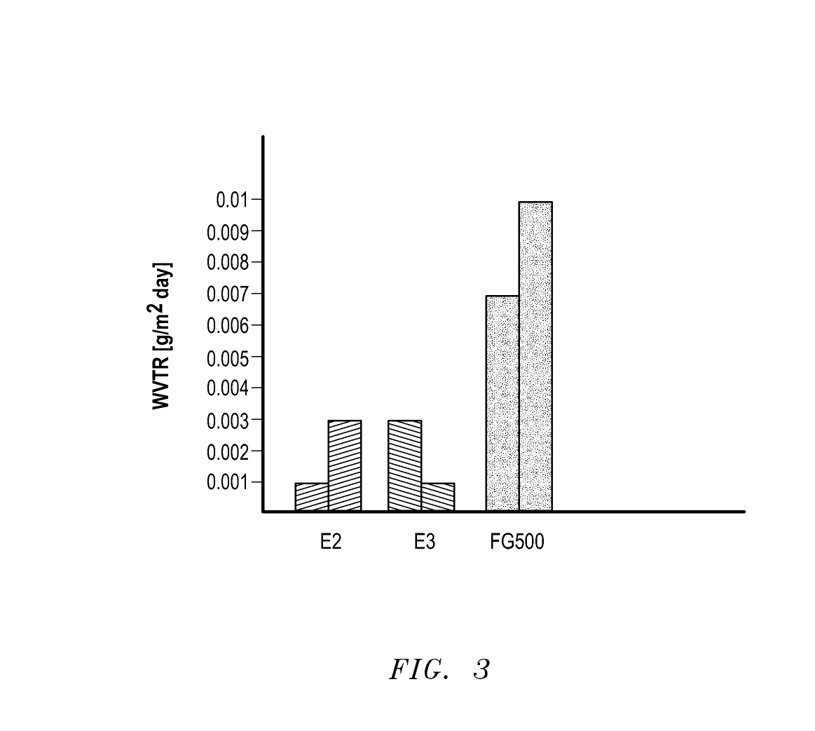

The Water Vapor Transmission Rate (WVTR) has been measured according to standard MOCON Aquatran method for silicon nitride layers of Examples 2 and 3, as well as for reference probe FG500. The results are shown in Table 2 and FIG. 3. The bar graph in FIG. 3 demonstrates that Examples E2 and E3 have a much lower WVTR than the commercial reference product FG500. This is a further proof of the advantageous moisture barrier performance of the silicon nitride layers according to the present invention.

TABLE 2
MOCON Aquatran test results:
Temperature: 38° C.; Humidity: 100% RH;
Carrier gas flow rate: 50 sccm;
Test area: 20 cm²; Pressure
(gauge): 10 psi (0.68 atm)

| | | Thickness of PET | |
|---|---|---|---|
| | | substrate | WVTR |
| Sample | Specimen | [mm] | [g/m²/day] |
| E2 | 1 | 0.127 | 0.001 |
| | 2 | 0.127 | 0.003 |
| E3 | 1 | 0.127 | 0.003 |
| | 2 | 0.127 | 0.001 |
| FG500 | 1 | 0.180 | 0.01 |
| | 2 | 0.180 | 0.007 |

### Example 9

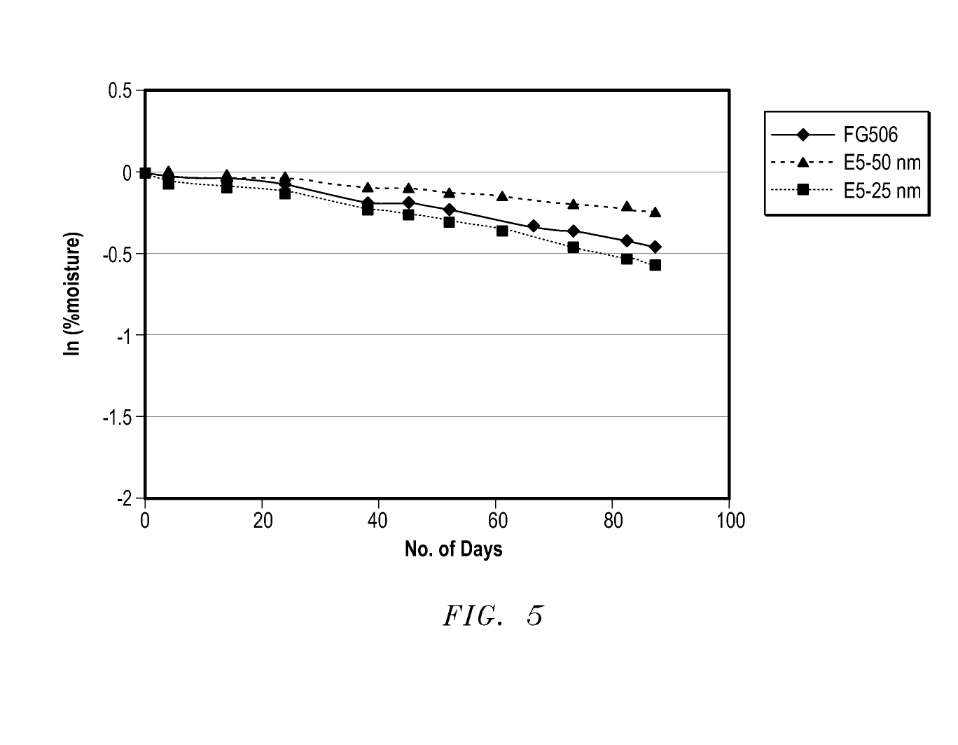

In order to determine the critical thickness of the silicon nitride layers with regard to a barrier performance as least as good as the barrier performance of commercial reference barrier layer FG500, silicon nitride layers of Example 5 have been made with a thickness of 50 nm and 25 nm. As demonstrated in FIG. 5, a thickness of 50 nm still has clear advantages compared to commercial reference FG500 barrier, while a thickness of 25 nm is slightly inferior to the barrier performance of reference FG500.

### Example 10

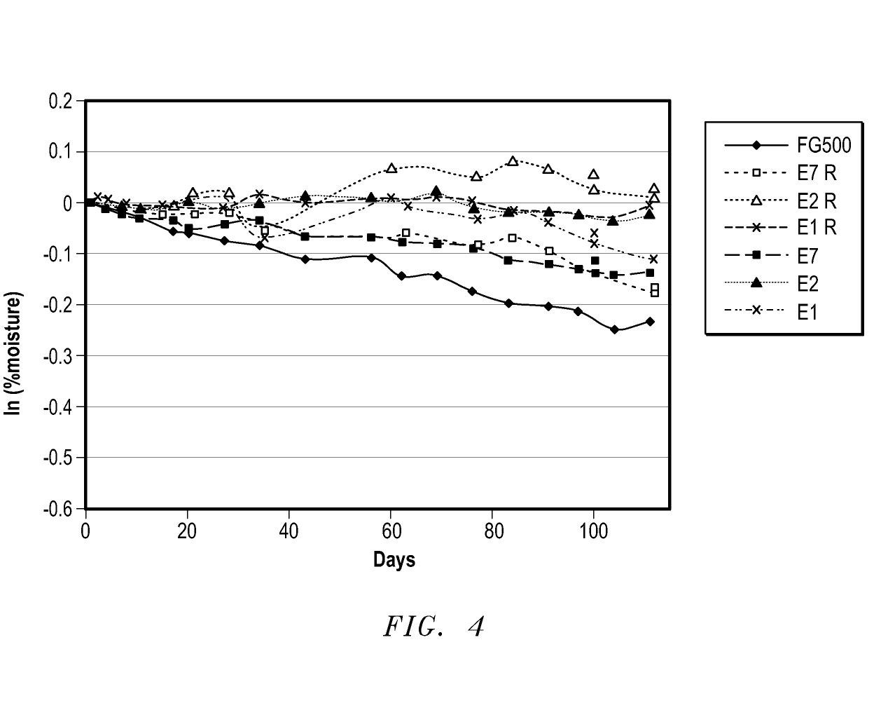

Substrates with deposited silicon nitride layers according to Examples 1, 2, and 7 have been subjected to a thermal treatment at 150° C. for 15 minutes in order to simulate a lamination cycle. The results are summarized in FIG. 4. It can be seen that the moisture bather performance of Examples 1, 2, and 7 after the thermal treatment (E1 R, E2 R, and E7 R), have only a minor decrease in their moisture barrier performance and are still better than the commercial reference FG500.

### Stress Measurement:

The stress has been measured according to VEECO's Stress Measurement Analysis using a DEKTAK Stylus Profiler. The stress measurement analysis employs the bending plate method which calculates the stress in a deposited thin film layer based upon the change in curvature and material properties of the film and substrate. The VEECO method described in “Thin Film Stress Measurement Using Dektak Stylus Profilers”, 2004, is expressly incorporated by reference herein.

Having now fully described this invention, it will be understood to those of ordinary skill in the art that the methods of the present invention can be carried out with a wide and equivalent range of conditions, formulations, and other parameters without departing from the scope if the invention or any embodiments thereof.

1. An article comprising:
a polymeric substrate, and
at least one inorganic barrier layer, wherein the inorganic barrier layer has a stress not greater than about 400 MPa and a density of at least about 1.5 g/cm³.

2. The article according to claims 1, wherein the substrate is flexible.

3. (canceled)

4. The article according to claim 1, wherein the density is at least about 2 g/cm³ and not greater than about 2.85 g/cm³.

5. The article according to any one of claim 1, wherein stress and density are related according to the following formula
Stress<S*Density+I,
wherein S has a value not greater than 550 MPa·cm³/g; and wherein I is not greater than −400 MPa.

6. The article according to claim 5, wherein S is 539 MPa·cm³/g and I is −915 MPa.

7. The article according to claim 1, wherein the inorganic barrier layer having a stress of not greater than about 170 MPa and a density of at least about 2.0 g/cm³.

8. The article according to any one of claim 1, wherein the inorganic barrier layer having a stress of not greater than about 350 MPa and a density of at least about 2.5 g/cm³.

9. The article according to any one of claim 1, wherein the polymeric substrate includes polyethylene terephthalate (PET), polyethylene naphthalate (PEN), polycarbonate, polyurethane, polymethyl methacrylate, polyamide, a fluoropolymer, or any combination thereof.

10. The article or the encapsulated optical device of claim 14, wherein the polymeric substrate consists essentially of polyethylene terephthalate (PET), polyethylene naphthalate (PEN), or a combination thereof.

11. The article according to claim 1, wherein the polymeric substrate is a transparent polymer with a transparency from 400 nm to 750 nm of at least 80%.

12. (canceled)

13. The article according to any one of claim 1, wherein the inorganic barrier layer comprises a metal oxide, a metal nitride, a metal oxynitride, or any combination thereof.

14. The article according to claim 13, wherein the inorganic barrier layer consists essentially of silicon nitride

15. The article according to claim 1, wherein the inorganic barrier layer has a water vapor transmission rate (WVTR) of not greater 0.005 g/m²/day.

16. The article according to claim 1, wherein the thickness of the at least one inorganic barrier layer is at least about 30 nm.

17. An encapsulated optical device comprising:
an electronic part; and
a barrier stack overlying the electronic part, wherein the barrier stack comprises
a polymeric substrate, and
an inorganic barrier layer, the inorganic barrier layer having a stress of not greater than about 400 MPa and a density of at least about 1.5 g/cm³.

18. The encapsulated optical device of claim 17, wherein the encapsulated optical device is an Organic Light Emitting Diode (OLED) or a photovoltaic (PV) module.

19. A method of making a silicon nitride layer on a polymeric substrate, wherein the silicon nitride layer has a stress not greater than about 400 MPa and a density of at least about 1.5 g/cm³, the method comprising depositing silicon nitride on the polymeric substrate.

20. The method according to claim 19, wherein the depositing includes Plasma Enhanced Chemical Vapor Deposition (PECVD).

21. The method of making a silicon nitride layer on a polymeric substrate according to claim 20, wherein the PECVD is conducted in a chamber having a reactor, the method further comprising:
adding SiH₄ and NH₃ to the chamber, a molar ratio of SiH₄/NH₃ being between about 0.4 to about 1.0;
heating the chamber to a temperature between about 70° C. to about 130° C.;
adjusting a pressure in the chamber between about 225 μbar to about 500 μbar; and
emitting radio frequency from the reactor at a power between about 200 W to about 450 W.

22. The method of making a silicon nitride layer on a polymeric substrate according to claim 21, wherein the molar ratio of SiH₄ to NH₃ is between about 0.5 to about 0.9; and wherein the chamber temperature is between about 80° C. to about 120° C.
